(19) United States
(12) Patent Application Publication
(10) Pub. No.: US 2013/0082931 A1
(43) Pub. Date: Apr. 4, 2013

(54) KEYBOARD INPUT DEVICE AND THE MANUFACTURING METHOD THEREOF

(71) Applicant: GE MEDICAL SYSTEMS GLOBAL TECHNOLOG, Waukesha, WI (US)

(72) Inventors: Bo TANG, Wuxi (CN); Chuanju CAO, Wuxi (CN); Hongwei YE, Wuxi (CN); Houzhi LUO, Wuxi (CN)

(73) Assignee: GE MEDICAL SYSTEMS GLOBAL TECHNOLOGY COMPANY, LLC, Waukesha, WI (US)

(21) Appl. No.: 13/626,949

(22) Filed: Sep. 26, 2012

(30) Foreign Application Priority Data
Sep. 30, 2011 (CN) 201110310335.X

(51) Int. Cl. G06F 3/02; H05K 13/00

(52) U.S. Cl. 345/168; 29/592.1

(57) ABSTRACT

A keyboard input device and a manufacturing method thereof is provided. The keyboard input device comprises a keyboard assembly having at least one key, a sensing device configured to sense the position of a key that produces a trigger action and to create a corresponding output signal, and a controller configured to receive the output signal from the sensing device and determine the key producing the trigger action.

### BACKGROUND OF THE INVENTION

Embodiments of the present invention generally relate to a keyboard input device and a manufacturing method thereof, in particular to a customizable keyboard input device and a manufacturing method thereof. A variety of keyboard input devices are well known, these keyboard input devices are used in systems such as computers, handheld devices and industrial instruments. Keyboard input devices for these systems are typically designed as mechanical keyboard input devices. In these mechanical keyboard input devices, keyboard layouts are generally fixed, that is, after the product leaves the product line, it is difficult for users to customize the layout of mechanical or touchscreen keys as needed. This lack of customization is disadvantageous for some devices, especially in medical instruments, wherein potential users, including physicians, may encounter a variety of patients, such as pregnant women, infants, and the elderly. Additionally, the same instrument may have many different functions, creating a need for a customizable layout of keys.

A conventional mechanical keyboard input device is disclosed in U.S. Pat. No. 5,872,527. It has projecting mechanical keys and flat keys. Such a keyboard input device is simple in shape and function, but complex in structure and hardware. The layout of the keyboard cannot be changed, unless lower PCBs (print circuit boards), keys, and top covers are replaced. This makes it difficult to realize customization of the product.

For the above problems, a touchscreen type keyboard input device is disclosed in US Patent No. 2011/0090151, which has a variety of embedded touchscreen keyboard interfaces. However, the customizable keyboard input device realized by a touchscreen provides unnecessary display functions, causing expensive costs. Moreover, a touchscreen keyboard input device is highly sensitive and has the problem of easily causing disoperation. Additionally, touchscreens are easily polluted, scratched and difficult to clean, so that it is not suitable for some conditions, especially in the applications of medical instruments.

Therefore, there is a need to provide a customizable keyboard input device, which can not only realize a customizable keyboard layout, but also has advantages of a conventional keyboard input device and/or overcome the disadvantages of a touchscreen type keyboard input device. Additionally, it is desirable to provide a manufacturing method for manufacturing the customizable keyboard input device as described above.

### BRIEF SUMMARY OF THE INVENTION

Embodiments of the present invention provide a customizable keyboard input device and a manufacturing method thereof.

According to an embodiment of this invention, a keyboard input device is provided. The keyboard input device comprises a keyboard assembly having at least one key, a sensing device configured to sense a position of a key producing a trigger action and to create a respective output signal, and a controller configured to receive the output signal from the sensing device and determine the key producing the trigger action.

According to another embodiment of the invention, a method for manufacturing a customizable keyboard input device is provided. The method comprises providing a keyboard assembly having at least one key; providing a sensing device which is configured to sense the position of a key producing a trigger action and to create a respective output signal; and providing a controller which is configured to receive the output signal from the sensing device and to determine the key producing said trigger action.

### BRIEF DESCRIPTION OF THE DRAWINGS

Features, aspects and advantages of embodiments of the invention may be better understood by reading the following description and referring to the accompanied figures. Similar labels represent similar components throughout all figures, wherein:

FIG. 1 is a schematic view of one embodiment of a keyboard input device of the present invention;

FIG. 2 is a key layout of an exemplary keyboard assembly of the keyboard input device illustrated in FIG. 1 according to this invention;

FIG. 3 is an illustrative and non-restrictive flowchart of using a keyboard input device according to embodiments of the present invention; and

FIG. 4 is a schematic view of an application of a keyboard input system according to this inventive technology.

### DETAILED DESCRIPTION OF THE INVENTION

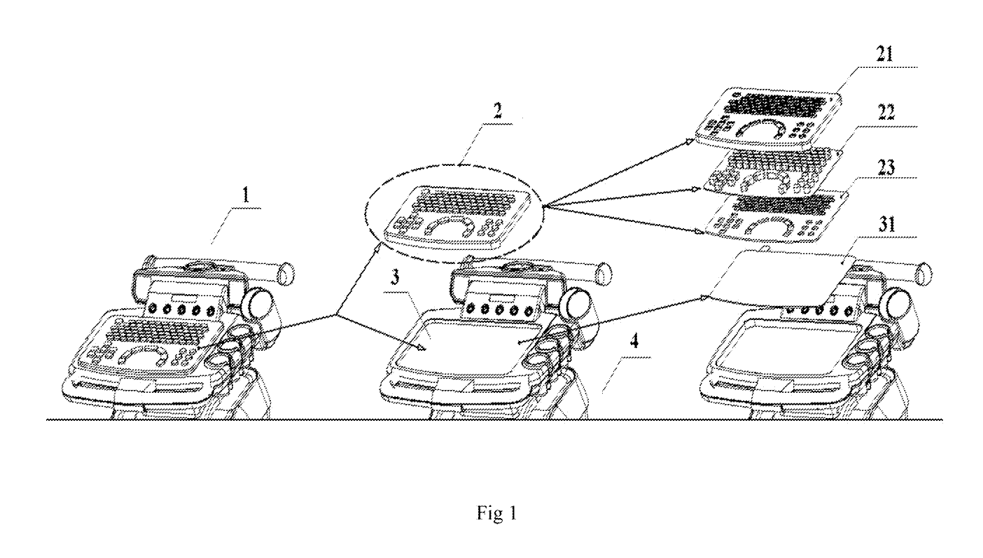

According to an embodiment of the invention, a keyboard input device 1, as illustrated in FIG. 1, which includes a keyboard assembly 2, is provided. The keyboard assembly may be a conventional mechanical key structure. The keyboard assembly may include, but is not limited to, a keyboard top cover 21, which includes an opening for each of the keys, in order for the key to pass therethrough. Amounts, sizes and positions of the openings correspond to the key layout, and can be set arbitrarily as needed. The keyboard top cover 21 can be made of a variety of suitable materials, in order to have a certain mechanical strength, and provide a variety of desired properties such as corrosion resistance, antibacterial property, etc.

The keyboard assembly 2 can also include a keyboard 22, which has at least one key. Amounts, sizes and positions of the keys correspond to the layout of the openings in the keyboard top cover 21, and can be set arbitrarily as needed. The keyboard 22 may be transparent, translucent or opaque, and any of its surfaces may include any labels such as characters or patterns. The keyboard 22 may be made of, for example, rubber or plastic, and used with illumination equipment, and provide a variety of required properties such as corrosion resistance, antibacterial property, etc.

If necessary, the keyboard assembly 2 may also include a corresponding support 23, in order to provide support for the keyboard 22 made of soft materials such as rubber. The support 23 is notched with holes corresponding to each of the keys, in order to allow at least part of each key to pass therethrough after being actuated.

Two or more of the keyboard top cover 21, the keyboard 22 and the support 23 of the keyboard assembly 2 can also form a one-piece structure. The keyboard assembly 2 of this invention can also be any mechanical keyboard equipment known in the art.

According to another embodiment of this invention, the input device 1 may also include a sensing device 3. The sensing device 3 is used for sensing a trigger action of a key, and creates a corresponding output signal. At least part of the area of the sensing device 3 is arranged behind a key area in the keyboard assembly 2, such that the key can contact with the area upon the trigger action. The size of the sensing device 3 is no less than the size of the key area in the keyboard assembly 2, such that the trigger actions of all keys in a variety of customized keyboard layout can be sensed.

The sensing device 3 according to embodiments of the present invention may be a sensing film 31, such as a resistance or capacitance type pressure film, or any other sensing device known in the art. As understood by one skilled in the art, if a resistance type pressure film is used, the keyboard assembly only needs to be designed such that the key can be pressed on the resistance type pressure film when the key is triggered or pressed. The resistance type pressure film can thus generate an output signal indicating the position being pressed. As to capacitance type pressure film, the key can be designed as grounded so that the capacitance type pressure film can sense the contact position when the key contacts with the capacitance type pressure film.

The output signal produced by the sensing device 3 according to embodiments of the present invention may be a signal which can include any information uniquely indicating the key producing a trigger action, such as a signal which includes position information of the key, or a signal which includes one or more coordinates of the key.

According to another embodiment of this invention, the input device may also include a controller 5. The controller 5 is used for receiving output signals from the sensing device 3, and determining which key produces the trigger action. The controller 5 can be designed to be accommodated in the keyboard assembly 2 or other position, e.g. in the console 4. The controller 5 can be provided with any information which is uniquely matched with information included by a signal from the sensing device 3 characterizing a key producing a trigger action. The information is may be, for example, a key map corresponding to a key layout of the keyboard assembly 2, which key map includes position information about each key, such as information about one or more coordinates of each key. According to a variety of different key layouts of the keyboard assembly, corresponding matched information (e.g., key maps matched with different key layouts) can be provided to the controller 5, for example, using a matched key map according to different keyboard layout, so as to make it possible to customize the key layouts.

According to an embodiment of the present invention the key map of the key can be stored in virtual memory. The controller 5 can then access the key map by retrieving it from the virtual memory.

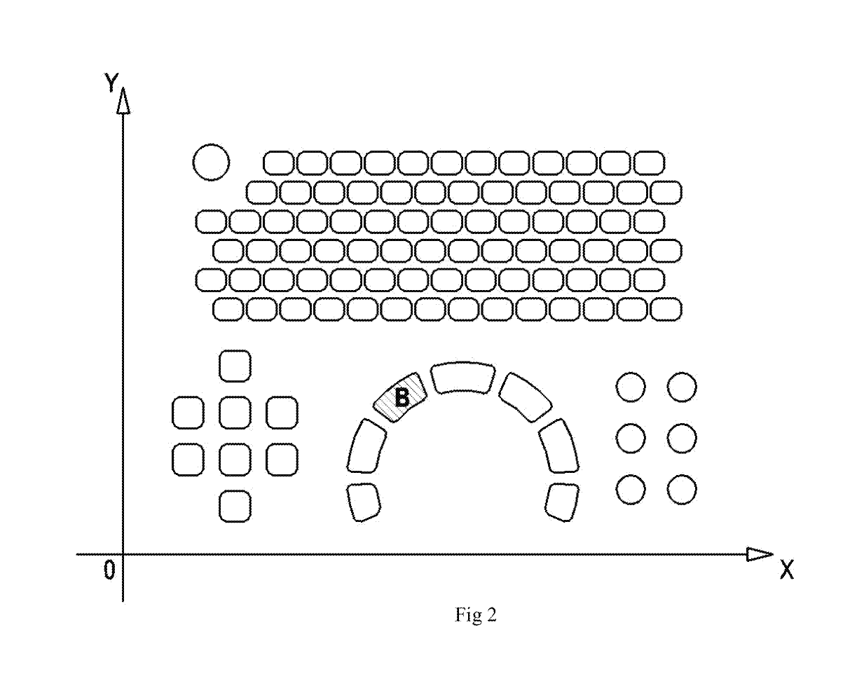

The input device 1 according to embodiments of the present invention can use a variety of different key layouts. FIG. 2 shows an exemplary keyboard layout, including several different areas, each area having keys with different amounts, sizes and distributions, in order to realize different functions. It can be understood that each key shown in FIG. 2 can be represented by a two dimensional coordinates X and Y. The function of each key can be determined by the key map. Thus, the keyboard layout can be easily customized.

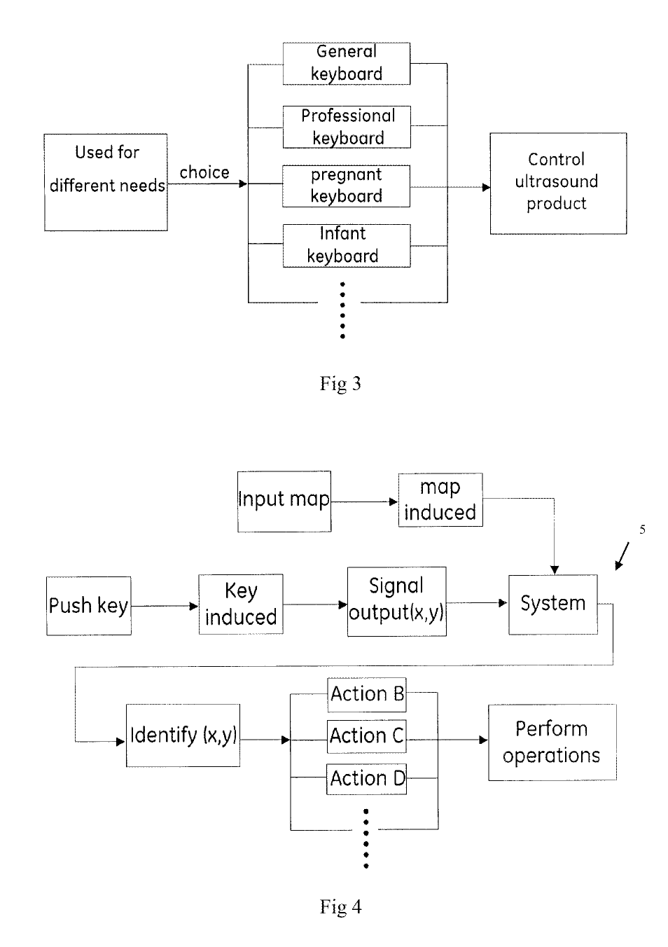

FIG. 3 illustrates a flowchart of using the keyboard input device of the present application in different conditions. As illustrated in FIG. 3, first, different key layouts can be chosen per different needs, such as general keyboard layouts, specific keyboard layouts, keyboard layouts for pregnant women, keyboard layouts for infants, etc., so that these keyboard layouts described above can be used in different equipment, and can also be used in the same equipment but oriented for different users, so as to maximize convenience for users. Then, in the controller 5, a corresponding key map is chosen or corresponding amendments are made to the key map. Lastly, the key input device is used to control a device.

In one embodiment of the invention, a different keyboard assembly 2 can be used to realize a different keyboard layout. Of course, corresponding amendments should be made to the key map so that the key map can match the replaced keyboard assembly 2. In another embodiment of the invention, it is possible to use the same keyboard assembly to realize a different keyboard layout by amending the key map.

Optionally, a switch means (not shown) can be provided. The controller 5 can determine the keyboard layout by detecting the states of the switch means, and thereby a corresponding key map is used. For example, for some medical devices, a keyboard assembly for use with pregnant women and a keyboard assembly for use with infants. The switch means will occupy a first state or a first position upon the installment of the keyboard assembly for pregnant women. The controller 5 will use a key map corresponding to the keyboard layout for pregnant women by detecting the state of the switch means. The switch means will occupy a second state or a second position upon the installment of the keyboard assembly for infants. The controller 5 will use a key map corresponding to the keyboard layout for an infant by detecting the state of the switch means. With such arrangement, the controller 5 can automatically be adapted to a different keyboard layout. One skilled in the art can understand that, with the same method, the keyboard input device can flexibly use more than two keyboard layouts or keyboard assemblies. Thus, different keyboard layouts can be flexibly used by replacing the keyboard assembly.

It should be understood that the change of the state of the switch means can be performed manually or automatically. One skilled in the art can think of various methods to realize automatic switching. For example, the switch means can be an on-off switch means. A first configuration of the keyboard assembly is configured to not press the switch means upon installation, and a second configuration of the keyboard assembly is configured to press the switch means upon installation.

The keyboard assembly 2 in the input device 1 according to embodiments of the present invention can also be designed to be detachable, in order for users to replace the keyboard assembly 2 freely, so as to realize free customization of the key layout.

Embodiments of this invention described above enable users to very conveniently and freely customize the keyboard layout as needed, and users can quickly develop a variety of derivative products based on the embodiments, so as to significantly reduce developing costs and shorten developing periods.

According to yet another embodiment of this invention, a manufacturing method of the keyboard input device 1 is provided. The manufacturing method comprises providing a keyboard assembly 2 as described previously, a sensing device 3 as described previously, and a controller 5 as described previously.

According to yet another embodiment of this invention, a keyboard input method is provided. As illustrated in FIG. 4, the method comprises providing a customizable key layout, and setting a key map corresponding to the key layout, which key map indicates position information of each key. The position information may be coordinate information corresponding to each key. The coordinate information can represent one or more coordinates of each key position or coordinate(s) within proximity of the position.

Referring to FIG. 2, the key map can be established in the following way: setting a coordinate system XOY, under which coordinate system, coordinate information corresponding to each key is acquired, wherein the coordinate information may be, for example, coordinate of the center of each key, or for example, one or more coordinates of the border of each key. The key map comprising coordinates information can be stored in the controller 5. One skilled in the art can understand that various coordinate formats can be used as desired.

When any key is pressed, a trigger action is created, which is sensed, and an output signal is created which comprises position information of the pressed key producing the trigger action; the output signal as described above is input into the controller 5, which ascertains position information directly or after treatment from the output signal, and compares the position information with a key map, so as to determine which key produces the trigger action. The controller 5 or equipment connected thereto can create further actions according to instructions corresponding to the pressed key.

In case a switch means is provided, the controller 5 can read the state of the switch means so that the corresponding key map is chosen.

The position information above may also be any mapping information which can uniquely determine each key.

It is easy to customize different keyboard layouts as needed with the keyboard input device of embodiments of the present invention. Moreover, the deficiencies of the mechanical keyboard or touchscreen keyboard can be overcome. The relative cost can be significantly reduced since the keyboard input device can be used in different conditions. It is also helpful for the process of product development. It should be understandable that the keyboard input device can provide a personalized keyboard input device for the users.

In one embodiment, the output signal can be a signal comprising position information of the key producing the trigger action. The controller may compare the position information with a key map corresponding to a key layout of the keyboard assembly, thereby determining the key producing the trigger action. The sensing device can be a sensing film. The layout of the keyboard assembly can be customized. The keyboard assembly can be detachable. The keyboard assembly can include a keyboard top cover and a keyboard. The keyboard assembly can also include a support. The position information can comprise one dimensional position information of the key or two dimensional position information of the key.

According to another embodiment of the invention, a keyboard input method is provided. The method comprises providing a key map corresponding to a key layout of a keyboard assembly, which key map stores information about a second position of each of keys, sensing a trigger action of a pressed key, and creating an output signal including information of a first position of the pressed key which produces the trigger action. The method further comprises comparing the second position information with the first position information, and determining which key produces the trigger action.

Different aspects of the device and method as described above may be used in different applications (e.g., used in controller systems of medical instruments). Although only some features of the invention are shown and described, many modifications and alterations may occur to those skilled in the art. Therefore, it should be understood that the appended claims are intended to cover all modifications and alterations falling into the spirit of this invention.

What is claimed is:

1. A keyboard input device comprising:
a keyboard assembly having at least one key;
a sensing device configured to sense a position of a key producing a trigger action and to create a respective output signal; and
a controller configured to receive the output signal from the sensing device and determine the key producing the trigger action.

2. The input device according to claim 1, wherein the output signal is a signal including position information of the key producing the trigger action.

3. The input device according to claim 2, wherein the controller compares the position information with a key map corresponding to a key layout of the keyboard assembly to determine the key producing the trigger action.

4. The input device according to claim 1, wherein the sensing device is a sensing film.

5. The input device according to claim 3, wherein the key map can be changed to customize the key layout of the keyboard assembly.

6. The input device according to claim 3, further comprising a switch having different states corresponding to different key layouts, wherein the controller selects a respective key map based on the state of the switch.

7. The input device according to claim 2, wherein the position information comprises one dimensional position information of the key or two dimensional position information of the key.

8. The input device according to claim 1, wherein the keyboard assembly comprises a keyboard top cover and a keyboard.

9. The input device according to claim 8, wherein the keyboard assembly further comprises a support.

10. A method of manufacturing a keyboard input device, the method comprising:
providing a keyboard assembly, the keyboard assembly having at least one key;
providing a sensing device configured to sense the position of a key producing a trigger action, and to create a respective output signal; and
providing a controller configured to receive the output signal from the sensing device and to determine the key producing the trigger action.

11. The method according to claim 10, wherein the output signal is a signal including position information of the key producing the trigger action.

12. The method according to claim 11, wherein the controller compares the position information with a key map corresponding to a key layout of the keyboard assembly to determine the key producing the trigger action.

13. The method according to claim 10, wherein the sensing device is a sensing film.

14. The method according to claim 12, wherein the key map can be changed to customize the key layout of the keyboard assembly.

15. The method according to claim 12, wherein the keyboard input device further comprises a switch having different states corresponding to different key layouts, wherein the controller selects a respective key map based on the state of the switch.

16. The method according to claim 11 wherein the position information comprises one dimensional position information of the key or two dimensional position information of the key.

17. The method according to claim 10, wherein the keyboard assembly comprises a keyboard top cover and a keyboard.

18. The method according to claim 15, wherein the keyboard assembly further comprises a support.
